(19) United States
(12) Patent Application Publication
(10) Pub. No.: US 2026/0363082 A1
(43) Pub. Date: Nov. 12, 2026

(54) NITRIDE SEMICONDUCTOR DEVICE AND MANUFACTURING METHOD THEREOF

(71) Applicant: Champ-Asia Semiconductor Corporation, Hsinchu City (TW)

(72) Inventor: Chun-Chieh Li, Hsinchu City (TW)

(21) Appl. No.: 19/360,285

(22) Filed: Oct. 16, 2025

(30) Foreign Application Priority Data
May 9, 2025 (TW) 114117633

(51) Int. Cl. H10W 42/00; H10D 30/47; H10D 62/85; H10F 30/222; H10F 77/124; H10P 14/20

(52) U.S. Cl. CPC H10W 42/121; H10D 30/475; H10D 62/8503; H10F 30/222; H10F 77/1246; H10P 14/3216; H10P 14/3252; H10P 14/3416

(57) ABSTRACT

A nitride semiconductor device and a manufacturing method thereof are provided. The nitride semiconductor device comprises a substrate, a nitride epitaxial composite layer, and a transition composite layer. The transition composite layer is sandwiched between the substrate and the nitride epitaxial composite layer and includes a first compound semiconductor and a second compound semiconductor, each selected from a group consisting of binary or ternary compound semiconductors composed of nitrogen (N), aluminum (Al), and gallium (Ga), and combinations thereof. The transition composite layer has an aluminum content that increases closer to the substrate.

### CROSS-REFERENCES TO RELATED APPLICATIONS

This application claims the benefit of priority to Taiwanese Patent Application No. 114117633 filed on May 9, 2025, which is hereby incorporated by reference in its entirety.

### BACKGROUND OF THE INVENTION

### Field of the Invention

The present invention relates to a nitride semiconductor device and a manufacturing method thereof, and more particularly to a nitride semiconductor device and a manufacturing method thereof for controlling warpage of an epitaxial layer.

### Descriptions of the Related Art

Nitride semiconductor devices, such as those based on gallium nitride (GaN) and related materials, are widely recognized as ideal wide-bandgap compound semiconductors. These materials have been applied in optoelectronic devices such as light-emitting diodes (LEDs), laser diodes, and photodiodes, as well as in non-optoelectronic devices such as field-effect transistors (FETs) and field emitters. In optoelectronic applications, the wide bandgap of GaN materials enables light emission or absorption in the visible to ultraviolet spectrum. In non-optoelectronic applications, GaN and its related materials offer high electron mobility and allow operation at very high signal frequencies.

In certain applications, GaN materials need to be epitaxially grown on a substrate. Compared to other substrate materials, silicon (Si) substrates offer a cost-effective advantage for GaN growth. Silicon substrates provide benefits such as low cost and good thermal conductivity, making them particularly suitable for fabrication with larger wafer sizes. Additionally, growing GaN layers on silicon substrates facilitates the integration of microelectronic and optoelectronic components. However, due to significant lattice constant and thermal expansion coefficient mismatches between GaN and silicon, directly growing single-crystal GaN layers on silicon substrates poses considerable challenges. Similarly, lattice constant mismatches between GaN and other substrate materials make it difficult to grow high-quality GaN layers. Lattice mismatch can lead to defects in the GaN layer grown on the substrate, which may degrade the performance of nitride semiconductor devices.

To address these issues, prior art techniques have proposed incorporating a buffer layer between the silicon substrate and the GaN bulk layer. This buffer layer has a smaller in-plane lattice constant than the GaN bulk material, mitigating lattice and thermal mismatches and suppressing crack growth in the GaN layer. For example, in the epitaxial structure of a high electron mobility transistor (HEMT), a nitride buffer layer is used to alleviate lattice mismatch between the substrate and the two-dimensional electron gas (2DEG) structure. However, a buffer layer with a smaller in-plane lattice constant introduces compressive strain to the GaN layer during epitaxial growth, leading to warpage of the epitaxial layer, increased leakage current, and reduced device reliability. Therefore, there remains a need to develop improved techniques to reduce severe defects caused by excessive stress, prevent crack propagation from the substrate to the surface of the epitaxial layer, and enhance device characteristics.

### SUMMARY OF THE INVENTION

The primary objective of the present invention is to provide an innovative nitride semiconductor device and a manufacturing method thereof that control stress differences between the substrate and the epitaxial layer for preventing excessive warpage, defect formation, and surface cracking in the epitaxial layer. Specifically, a stress control epitaxial structure is disposed between the substrate and the active layer of the device. This structure comprises at least one carbon-doped layer stacked alternately and is synthesized using metal-organic chemical vapor deposition with binary and ternary compound semiconductors composed of nitrogen, gallium, and aluminum, with aluminum content ranging from 0% to 100%. This structure controls the accumulated stress between the substrate and the upper 2DEG active layer for suppressing wafer warpage and surface cracking, and increasing the device breakdown voltage.

To achieve the above objective, the present invention provides a nitride semiconductor device comprising a substrate, a nitride epitaxial composite layer, and a transition composite layer. The transition composite layer is sandwiched between the substrate and the nitride epitaxial composite layer and includes a first compound semiconductor and a second compound semiconductor, each selected from a group consisting of binary or ternary compound semiconductors composed of nitrogen (N), aluminum (Al), and gallium (Ga), and combinations thereof. The transition composite layer has an aluminum content that increases closer to the substrate.

In one embodiment of the nitride semiconductor device of the present invention, the transition composite layer includes a stress control composite layer comprising a plurality of aluminum gallium nitride layers (Al_{Xn}Ga_{(1-Xn)}N, 0<Xn<1), where n is a positive integer greater than 1 and represents a layer index, and the smaller the layer index, the closer the aluminum gallium nitride layer is to the substrate with a higher aluminum content.

In one embodiment of the nitride semiconductor device of the present invention, the aluminum gallium nitride layers have an overall aluminum content P, where P=[(x₁×d₁)+(x₂×d₂)+ . . . +(xₙ×dₙ)]/[d₁+d₂+ . . . +dₙ], and d represents the thickness of each aluminum gallium nitride layer, with each layer having a thickness of 1 to 300 nanometers (nm).

In one embodiment of the nitride semiconductor device of the present invention, each aluminum gallium nitride layer has a carbon doping concentration, with the carbon doping concentration increasing farther from the substrate, gradually increasing from 1E17 to 1E19 cm⁻3 to 1E17 to 1E22 cm⁻3.

In one embodiment of the nitride semiconductor device of the present invention, the transition composite layer further includes a buffer composite layer having a first buffer layer sandwiched between the stress control composite layer and the nitride epitaxial composite layer or between the stress control composite layer and the substrate. The first buffer layer is a composite layer comprising alternating stacks of an aluminum nitride layer and an aluminum gallium nitride layer (Al_{Xn}Ga_{(1-Xn)}N, 0<Xn<1), where n is a positive integer greater than 1, and when n is odd, Xn=1, and when n is even, 0≤Xn<1, with each aluminum nitride layer and each aluminum gallium nitride layer having a thickness of 1 to 50 nanometers (nm).

In one embodiment of the nitride semiconductor device of the present invention, the buffer composite layer has a carbon doping concentration that increases farther from the substrate, gradually increasing from 1E17 to 1E19 cm⁻3 to 1E17 to 1E22 cm⁻3.

In one embodiment of the nitride semiconductor device of the present invention, the buffer composite layer further includes a second buffer layer sandwiched between the stress control composite layer and the first buffer layer or between the stress control composite layer and the nitride epitaxial composite layer. The second buffer layer is a composite layer comprising alternating stacks of an aluminum nitride layer and an aluminum gallium nitride layer (Al_{Xn}Ga_{(1-Xn)}N, 0<Xn<1).

In one embodiment of the nitride semiconductor device of the present invention, the transition composite layer further includes a buffer composite layer having a first buffer layer sandwiched between the stress control composite layer and the nitride epitaxial composite layer or between the stress control composite layer and the substrate. The first buffer layer comprises alternating stacks of an aluminum nitride layer and an aluminum gallium nitride layer (Al_{Xn}Ga_{(1-Xn)}N, 0<Xn<1), where n is a positive integer greater than 1, and when n is odd, 0≤Xn<1, and when n is even, Xn=1, with each aluminum nitride layer and each aluminum gallium nitride layer having a thickness of 1 to 50 nanometers (nm).

In one embodiment of the nitride semiconductor device of the present invention, the buffer composite layer has a carbon doping concentration that increases farther from the substrate, gradually increasing from 1E17 to 1E19 cm⁻3 to 1E17 to 1E22 cm⁻3.

In one embodiment of the nitride semiconductor device of the present invention, the buffer composite layer further includes a second buffer layer sandwiched between the stress control composite layer and the first buffer layer or between the stress control composite layer and the nitride epitaxial composite layer. The second buffer layer is a composite layer comprising alternating stacks of an aluminum nitride layer and an aluminum gallium nitride layer (Al_{Xn}Ga_{(1-Xn)}N, 0<Xn<1).

To achieve the above objective, the present invention provides a manufacturing method for a nitride semiconductor device, comprising: providing a nitride epitaxial composite layer disposed on a substrate; and providing a transition composite layer sandwiched between the substrate and the nitride epitaxial composite layer, including a first compound semiconductor and a second compound semiconductor, each selected from a group consisting of binary or ternary compound semiconductors composed of nitrogen (N), aluminum (Al), and gallium (Ga), and combinations thereof, wherein the transition composite layer has an aluminum content that increases closer to the substrate.

In one embodiment of the manufacturing method for the nitride semiconductor device of the present invention, the step of providing a transition composite layer comprises providing a stress control composite layer comprising a plurality of aluminum gallium nitride layers (Al_{Xn}Ga_{(1-Xn)}N, 0<Xn<1), where n is a positive integer greater than 1 and represents a layer index, and the smaller the layer index, the closer the aluminum gallium nitride layer is to the substrate with a higher aluminum content.

In one embodiment of the method for manufacturing the nitride semiconductor device of the present invention, the step of providing a stress control composite layer comprises carbon doping each aluminum gallium nitride layer, with the carbon doping concentration increasing farther from the substrate, gradually increasing from 1E17 to 1E19 cm⁻3 to 1E17 to 1E22 cm⁻3.

In one embodiment of the method for manufacturing the nitride semiconductor device of the present invention, the carbon doping is performed using one of methane (CH₄), ethylene (C₂H₄), or pentane (C₅H₁₂) as a doping gas, chamber auto-doping, or diffusion.

In one embodiment of the method for manufacturing the nitride semiconductor device of the present invention, forming the stress control composite layer is performed using metal-organic chemical vapor deposition (MOCVD) or molecular beam epitaxy (MBE) with materials including trimethylgallium (TMGa), triethylgallium (TEGa), trimethylaluminum (TMAl), trimethylindium (TMIn), and ammonia (NH₃).

In one embodiment of the method for manufacturing the nitride semiconductor device of the present invention, the step of providing a transition composite layer further comprises providing a buffer composite layer having a first buffer layer sandwiched between the stress control composite layer and the nitride epitaxial composite layer or between the stress control composite layer and the substrate. The first buffer layer is a composite layer comprising alternating stacks of an aluminum nitride layer and an aluminum gallium nitride layer (Al_{Xn}Ga_{(1-Xn)}N, 0<Xn<1), where n is a positive integer greater than 1, and when n is odd, Xn=1, and when n is even, 0≤Xn<1, with each aluminum nitride layer and each aluminum gallium nitride layer having a thickness of 1 to 50 nanometers (nm).

In one embodiment of the method for manufacturing the nitride semiconductor device of the present invention, the step of providing a buffer composite layer comprises carbon doping the buffer composite layer, with the carbon doping concentration increasing farther from the substrate, gradually increasing from 1E17 to 1E19 cm⁻3 to 1E17 to 1E22 cm⁻3.

In one embodiment of the method for manufacturing the nitride semiconductor device of the present invention, the step of providing a buffer composite layer further comprises providing a second buffer layer sandwiched between the stress control composite layer and the first buffer layer or between the stress control composite layer and the nitride epitaxial composite layer. The second buffer layer is a composite layer comprising alternating stacks of an aluminum nitride layer and an aluminum gallium nitride layer (Al_{Xn}Ga_{(1-Xn)}N, 0<Xn<1).

In one embodiment of the method for manufacturing the nitride semiconductor device of the present invention, the step of providing a transition composite layer further comprises providing a buffer composite layer having a first buffer layer sandwiched between the stress control composite layer and the nitride epitaxial composite layer or between the stress control composite layer and the substrate. The first buffer layer comprises alternating stacks of an aluminum nitride layer and an aluminum gallium nitride layer (Al_{Xn}Ga_{(1-Xn)}N, 0<Xn<1), where n is a positive integer greater than 1, and when n is odd, 0≤Xn<1, and when n is even, Xn=1, with each aluminum nitride layer and each aluminum gallium nitride layer having a thickness of 1 to 50 nanometers (nm).

In one embodiment of the method for manufacturing the nitride semiconductor device of the present invention, the step of providing a buffer composite layer comprises carbon doping the buffer composite layer, with the carbon doping concentration increasing farther from the substrate, gradually increasing from 1E17 to 1E19 cm⁻3 to 1E17 to 1E22 cm⁻3.

In one embodiment of the method for manufacturing the nitride semiconductor device of the present invention, the step of providing a buffer composite layer further comprises providing a second buffer layer sandwiched between the stress control composite layer and the first buffer layer or between the stress control composite layer and the nitride epitaxial composite layer. The second buffer layer is a composite layer comprising alternating stacks of an aluminum nitride layer and an aluminum gallium nitride layer (Al_{Xn}Ga_{(1-Xn)}N, 0<Xn<1).

After referring to the drawings and the embodiments described subsequently, those skilled in the art will understand the other objectives of the present invention, as well as the technical means and embodiments of the present invention.

### BRIEF DESCRIPTION OF THE DRAWINGS

FIG. 1 is a schematic diagram of a nitride semiconductor device in one embodiment of the present invention;

FIG. 2 is a partially enlarged schematic diagram of the nitride semiconductor device of FIG. 1;

FIG. 3 is a schematic diagram of a nitride semiconductor device in another embodiment of the present invention;

FIG. 4 is a schematic diagram of a nitride semiconductor device in yet another embodiment of the present invention; and

FIG. 5 is a schematic diagram of process steps for manufacturing a nitride semiconductor device in one embodiment of the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

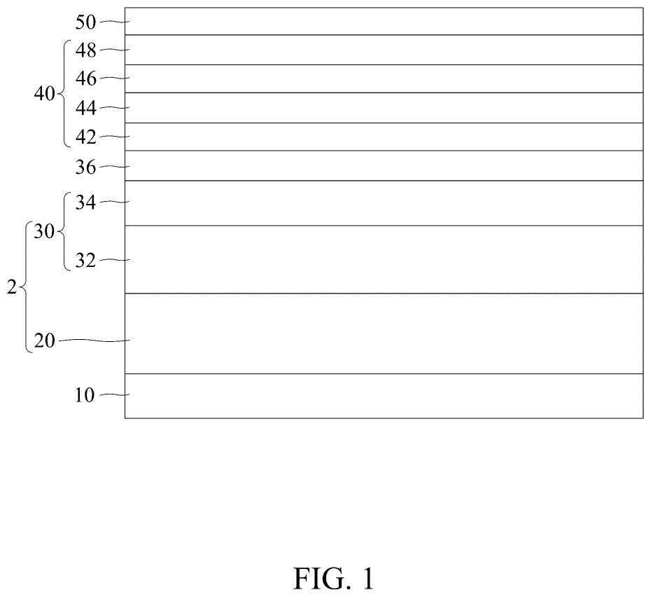

Referring to FIG. 1, a schematic diagram illustrates a nitride semiconductor device and a manufacturing method thereof in one embodiment of the present invention, particularly a high electron mobility transistor or a nitride photodiode and a manufacturing method thereof. The following description will use a high electron mobility transistor as an example of a nitride semiconductor device to illustrate the present invention, but it is not limited thereto. The nitride semiconductor device shown in FIG. 1 includes a substrate 10, a transition composite layer 2, a nitride epitaxial composite layer 40, and a cover layer 50.

Specifically, in this embodiment, the substrate 10 is a silicon substrate, but it is not limited thereto. In other embodiments, the substrate 10 may be a sapphire (Al₂O₃) substrate, a silicon carbide (SiC) substrate, a gallium nitride (GaN) substrate, or a gallium oxide (Ga₂O₃) substrate. This embodiment exemplifies a depletion-mode high electron mobility transistor, and thus, the nitride epitaxial composite layer 40, serving as the active layer of the device, comprises, from bottom to top closer to the substrate, a gallium nitride channel layer 42, an aluminum nitride spacer layer 44, an aluminum gallium nitride barrier layer 46, and an undoped gallium nitride cap layer 48. The gallium nitride channel layer 42 provides a conductive channel with high electron mobility, serving as the primary region for two-dimensional electron gas (2DEG) formation, and is undoped or has low background doping to ensure high mobility and low scattering. The aluminum nitride spacer layer 44 acts as an isolation barrier and channel layer, reducing interface roughness scattering to further enhance 2DEG mobility, with a thickness typically not exceeding 2 nanometers (nm), while providing an additional polarization field to increase 2DEG density. The aluminum gallium nitride barrier layer 46 leverages the piezoelectric and spontaneous polarization differences with the gallium nitride layer to induce high-density 2DEG, with an aluminum content of approximately 20% to 30% and a thickness of 20 to 30 nanometers (nm), typically undoped or lightly doped to stabilize the bandgap structure. Additionally, in this embodiment, the cover layer 50 is a silicon nitride layer serving as an insulating layer between field plates and a surface passivation layer, enhancing the device's breakdown voltage and reliability. Preferably, a carbon-doped gallium nitride layer 36 is disposed between the transition composite layer 2 and the nitride epitaxial composite layer 40 as a semi-insulating layer to suppress leakage current and electron migration.

Referring to FIG. 1, due to approximately 17% lattice constant mismatch and up to 56% thermal expansion coefficient mismatch between silicon and silicon nitride in the substrate 10 and the nitride epitaxial composite layer 40, directly growing a nitride epitaxial structure such as silicon nitride on a silicon substrate is highly prone to cracking, warpage, and high defect density. In view of this, the present invention incorporates a transition composite layer 2 sandwiched between the substrate 10 and the nitride epitaxial composite layer 40 to gradually reduce lattice and thermal expansion mismatches, suppress dislocation propagation to the upper active region, and thereby reduce warpage (or bowing) and stress-induced cracking, forming a highly insulating bottom layer to isolate the conductivity and leakage paths of the silicon substrate.

Specifically, the materials constituting the transition composite layer 2 of the present invention include a first compound semiconductor and a second compound semiconductor, each selected from a group consisting of binary or ternary compound semiconductors composed of nitrogen (N), aluminum (Al), and gallium (Ga), and combinations thereof. That is, the first compound semiconductor and the second compound semiconductor may be selected from a group consisting of aluminum nitride (AlN), gallium nitride (GaN), and aluminum gallium nitride (AlGaN), and combinations thereof. Particularly, a key feature of the present invention is that the transition composite layer 2 has an aluminum content that increases closer to the substrate 10. In other words, as the transition composite layer 2 is grown layer by layer upward from the substrate 10, the aluminum content is gradually reduced to mitigate lattice mismatch, avoid dislocation and crack formation, and improve epitaxial quality.

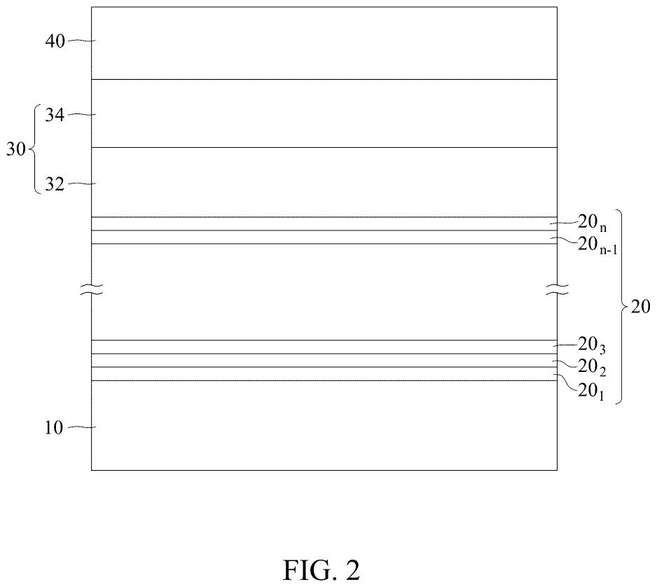

Referring to FIG. 1 and FIG. 2, the transition composite layer 2 includes a stress control composite layer 20. Specifically, the stress control composite layer 20 comprises a plurality of aluminum gallium nitride layers 20₁, 20₂, 20₃, . . . , 20ₙ₋₁, 20ₙ stacked together, where the composition ratio of aluminum to gallium in each aluminum gallium nitride layer is represented by Al_{Xn}Ga_{(1-Xn)}N, where 0<Xn<1, and n is a positive integer greater than 1, representing a layer index of the stress control composite layer. The aluminum content in each layer ranges from 0% to 100%, and the thickness of each aluminum gallium nitride layer is 1 to 300 nanometers (nm). In practical applications, the aluminum content in each layer can be adjusted to offset interlayer stress for reducing dislocation propagation upward and mitigating lattice mismatch between layers. Notably, a smaller layer index n indicates that the aluminum gallium nitride layer is closer to the substrate with a higher aluminum content for transitioning the lattice constant from closer to aluminum nitride to gallium nitride and reducing lattice dislocations and cracks to achieve the expected goals of lattice matching and stress management.

For example, when n=1, it represents the aluminum gallium nitride layer 20₁ adjacent to the upper surface of the substrate 10, which has the highest aluminum content. If the aluminum content of each aluminum gallium nitride layer in the stress control composite layer 20 is calculated and represented by an overall aluminum content P (%), this overall aluminum content P can be expressed using Equation 1 as shown below, and the aluminum content P₁ of the first aluminum gallium nitride layer 20₁ is greater than this overall aluminum content P. From a stress management perspective, layers closer to the substrate with high aluminum content (e.g., X₁=0.8 for aluminum gallium nitride layer 20₁) introduce compressive stress, while layers farther from the substrate with lower aluminum content (e.g., Xn=0.1 for aluminum gallium nitride layer 20ₙ) may introduce tensile stress. An overall aluminum content P less than P₁ indicates that the overall structure is closer to the composition of gallium nitride, facilitating lattice matching with the top gallium nitride layer.

P=[(x₁×d₁)+(x₂×d₂)+ . . . +(xₙ×dₙ)]/[d₁+d₂+ . . . +dₙ] (Equation 1)
where dₙ represents the thickness of the nₜₕ aluminum gallium nitride layer 20ₙ.

The stress control composite layer 20 can be formed by alternately stacking layers using thin-film deposition techniques, such as metal-organic chemical vapor deposition (MOCVD) or molecular beam epitaxy (MBE). Specifically, these thin-film deposition techniques may use materials including trimethylgallium (TMGa), triethylgallium (TEGa), trimethylaluminum (TMAl), trimethylindium (TMIn), and ammonia (NH₃) to form the plurality of aluminum gallium nitride layers 20₁, 20₂, 20₃, . . . , 20ₙ₋₁, 20ₙ.

Additionally, in nitride-based power devices, undoped gallium nitride or aluminum gallium nitride layers in the transition composite layer may have background carriers, leading to N-type conductivity and forming leakage currents. To reduce leakage current, increase resistivity, and enhance the breakdown voltage of the device, the transition composite layer is specifically carbon-doped to effectively control its conductivity, reduce parasitic current paths, and minimize interference with the upper active region. Taking the carbon-doped stress control composite layer 20 as an example, after carbon doping, each aluminum gallium nitride layer 20₁, 20₂, 20₃, . . . , 20ₙ₋₁, 20ₙ in the stress control composite layer 20 has a carbon doping concentration. Preferably, the carbon doping concentration increases farther from the substrate, gradually increasing from 1E17 to 1E19 cm⁻3 to 1E17 to 1E22 cm⁻3. In certain device applications, the aluminum gallium nitride layers in the stress control composite layer may also consist of alternating carbon-doped and undoped epitaxial structures. Furthermore, using carbon atoms as impurities introduces localized stress fields for adjusting interlayer stress distribution, reducing tensile stress accumulation, and achieving stress control.

Specifically, carbon doping can be performed using one of methane (CH₄), ethylene (C₂H₄), or pentane (C₅H₁₂) as a doping gas, chamber auto-doping, or diffusion. For example, the carbon doping concentration of the first aluminum gallium nitride layer 20₁ is approximately 1E17 to 1E19 cm⁻3, the second layer 20₂ is approximately 1E17 to 1E20 cm⁻3, the third layer 20₃ is approximately 1E17 to 1E21 cm⁻3, and the fourth layer 20₄ is approximately 1E17 to 1E22 cm⁻3. It should be noted that, in addition to carbon doping, iron doping may also be used in each aluminum gallium nitride layer 20₁, 20₂, 20₃, . . . , 20ₙ₋₁, 20ₙ, and when the iron doping concentration in aluminum-containing nitride layers increases closer to the active layer, it can also enhance insulation, increase device breakdown voltage, and reduce leakage current.

In practical applications, the transition composite layer 2 of the present invention further includes a buffer composite layer 30. As shown in FIG. 1, the buffer composite layer 30 includes a first buffer layer 32 sandwiched between the stress control composite layer 20 and the nitride epitaxial composite layer 40. The first buffer layer 32 is a composite layer comprising alternating stacks of an aluminum nitride layer and an aluminum gallium nitride layer (Al_{Xn}Ga_{(1-Xn)}N, 0≤Xn<1), where n is a positive integer greater than 1. The buffer composite layer adopts a superlattice-like structure, such as alternating aluminum nitride, gallium nitride, and aluminum gallium nitride layers, to further reduce dislocation density and improve crystal quality. Specifically, the first buffer layer 32 has at least two alternating stacking configurations. In the first stacking configuration, odd-numbered layers are aluminum nitride layers, and even-numbered layers are gallium nitride or aluminum gallium nitride layers. That is, when n is odd, Xn=1, and odd-numbered layers are aluminum nitride layers; when n is even, 0≤Xn<1, and even-numbered layers are gallium nitride or aluminum gallium nitride layers (Al_{Xn}Ga_{(1-Xn)}N, 0≤Xn<1), with each layer having a thickness of 1 to 50 nanometers (nm). In the second stacking configuration, the structure also comprises alternating aluminum nitride and aluminum gallium nitride layers (Al_{Xn}Ga_{(1-Xn)}N, 0<Xn<1), where odd-numbered layers are gallium nitride or aluminum gallium nitride layers, and even-numbered layers are aluminum nitride layers. That is, when n is odd, 0≤Xn<1, and odd-numbered layers are gallium nitride or aluminum gallium nitride layers; when n is even, Xn=1, and even-numbered layers are aluminum nitride layers, with each layer having a thickness of 1 to 50 nanometers (nm). Additionally, in both the first and second stacking configurations, the first buffer layer 32 preferably has a carbon doping concentration that increases farther from the substrate, gradually increasing from 1E17 to 1E19 cm⁻3 to 1E17 to 1E22 cm⁻3.

In practical applications, depending on lattice and stress adjustment requirements, a second buffer layer 34 may be further disposed in the buffer composite layer 30, sandwiched between the first buffer layer 32 and the nitride epitaxial composite layer 40, to further reduce dislocation density and improve crystal quality. The second buffer layer 34 is identical to the first buffer layer 32, being a composite layer comprising alternating stacks of an aluminum nitride layer and an aluminum gallium nitride layer (Al_{Xn}Ga_{(1-Xn)}N, 0<Xn<1). Similarly, the second buffer layer 34 may have the aforementioned two different stacking configurations and carbon doping concentration distributions, which are not repeated here.

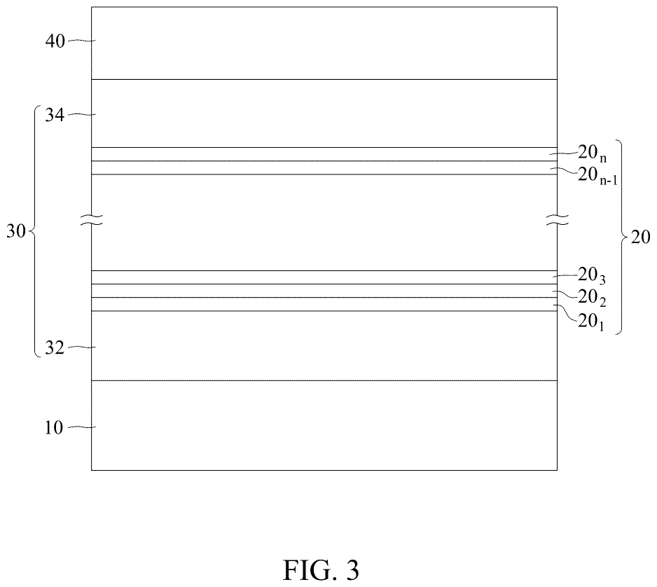

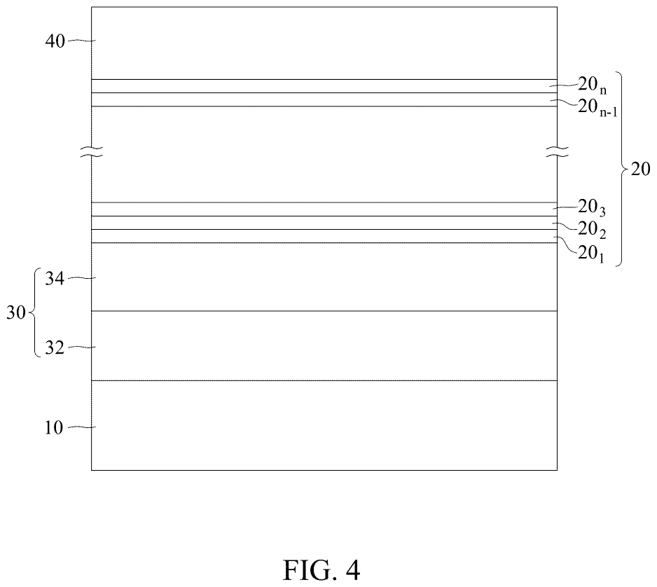

It should be noted that the stacking configurations of the stress control composite layer 20 and the buffer composite layer 30 in the transition composite layer 2 shown in FIG. 1 and FIG. 2 are merely one embodiment. In practical applications, the transition composite layer 2 may adopt different stacking configurations of the stress control composite layer 20 and the buffer composite layer 30 depending on the device structure. As shown in FIG. 3, the first buffer layer 32 is sandwiched between the stress control composite layer 20 and the substrate 10, while the second buffer layer 34 is sandwiched between the stress control composite layer 20 and the nitride epitaxial composite layer 40. Another possible embodiment, as shown in FIG. 4, illustrates the first buffer layer 32 and the second buffer layer 34 both sandwiched between the stress control composite layer 20 and the substrate 10. The stress control composite layer 20 and the buffer composite layer 30 shown in FIG. 3 and FIG. 4 are identical to those in the aforementioned embodiments and are not repeated here. Notably, in the aforementioned embodiments, the buffer composite layer 30 may consist solely of the first buffer layer 32 in conjunction with the stress control composite layer 20 without using the second buffer layer 34, which is also a possible embodiment of the present invention.

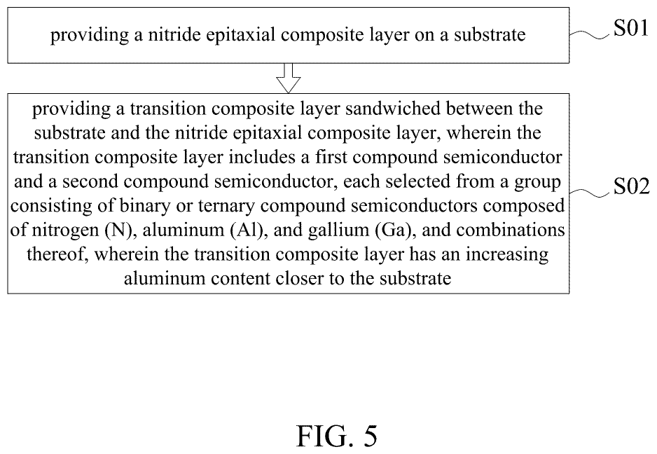

Referring to FIG. 5, a schematic diagram illustrates the process steps for manufacturing the semiconductor structure of the present invention. First, in step S01, a nitride epitaxial composite layer is provided on a substrate. Next, in step S02, a transition composite layer is provided, sandwiched between the substrate and the nitride epitaxial composite layer, including a first compound semiconductor and a second compound semiconductor, each selected from a group consisting of binary or ternary compound semiconductors composed of nitrogen (N), aluminum (Al), and gallium (Ga), and combinations thereof, wherein the transition composite layer has an aluminum content that increases closer to the substrate. The composition and relationships of the components in each process step can refer to the foregoing description and are not repeated here.

In summary, a key technical feature of the present invention lies in its principle of using a transition layer composed of at least two different materials selected from aluminum nitride, gallium nitride, and aluminum gallium nitride between the substrate and the nitride active layer to achieve stress control. Notably, the transition layer of the present invention avoids using indium-containing compound semiconductors, such as indium gallium nitride requiring low-temperature growth, to prevent thermal stress from high-to-low temperature transitions and limitations due to the low impedance characteristics of indium gallium nitride, which may lead to leakage under high breakdown voltages. In contrast, the heterojunction or graded layer structure of the transition composite layer of the present invention offers excellent thermal stability and lattice matching, making it suitable for manufacturing high-power, high-frequency, and high-brightness semiconductor devices.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A nitride semiconductor device, comprising:
a substrate;
a nitride epitaxial composite layer; and
a transition composite layer sandwiched between the substrate and the nitride epitaxial composite layer, including a first compound semiconductor and a second compound semiconductor, each selected from a group consisting of binary or ternary compound semiconductors composed of nitrogen (N), aluminum (Al), and gallium (Ga), and combinations thereof, wherein the transition composite layer has an increasing aluminum content closer to the substrate.

2. The nitride semiconductor device of claim 1, wherein the transition composite layer includes a stress control composite layer comprising a plurality of aluminum gallium nitride layers (Al_{Xn}Ga_{(1-Xn)}N, 0<Xn<1), where n is a positive integer greater than 1 and represents a layer index, and the smaller the layer index, the closer the aluminum gallium nitride layer is to the substrate with a higher aluminum content.

3. The nitride semiconductor device of claim 2, wherein the aluminum gallium nitride layers have an overall aluminum content P, where P=[(x₁×d₁)+(x₂×d₂)+ . . . +(xₙ×dₙ)]/[d₁+d₂+ . . . +dₙ], d represents a thickness of each of the aluminum gallium nitride layers, and the thickness of each of the aluminum gallium nitride layers is 1 to 300 nanometers (nm).

4. The nitride semiconductor device of claim 2, wherein each of the aluminum gallium nitride layers has a carbon doping concentration, with the carbon doping concentration increasing farther from the substrate, gradually increasing from 1E17 to 1E19 cm⁻3 to 1E17 to 1E22 cm⁻3.

5. The nitride semiconductor device of claim 2, wherein the transition composite layer further includes a buffer composite layer having a first buffer layer sandwiched between the stress control composite layer and the nitride epitaxial composite layer or between the stress control composite layer and the substrate, wherein the first buffer layer is a composite layer comprising alternating stacks of an aluminum nitride layer and an aluminum gallium nitride layer (Al_{Xn}Ga_{(1-Xn)}N, 0≤Xn<1), where n is a positive integer greater than 1, and when n is odd, Xn=1, and when n is even, 0≤Xn<1, with each of the aluminum nitride layers and each of the aluminum gallium nitride layers having a thickness of 1 to 50 nanometers (nm).

6. The nitride semiconductor device of claim 5, wherein the buffer composite layer has a carbon doping concentration increasing farther from the substrate, gradually increasing from 1E17 to 1E19 cm⁻3 to 1E17 to 1E22 cm⁻3.

7. The nitride semiconductor device of claim 6, wherein the buffer composite layer further includes a second buffer layer sandwiched between the stress control composite layer and the first buffer layer or between the stress control composite layer and the nitride epitaxial composite layer, wherein the second buffer layer is a composite layer comprising alternating stacks of an aluminum nitride layer and an aluminum gallium nitride layer (Al_{Xn}Ga_{(1-Xn)}N, 0≤Xn<1).

8. The nitride semiconductor device of claim 2, wherein the transition composite layer further includes a buffer composite layer having a first buffer layer sandwiched between the stress control composite layer and the nitride epitaxial composite layer or between the stress control composite layer and the substrate, wherein the first buffer layer comprises alternating stacks of an aluminum nitride layer and an aluminum gallium nitride layer (Al_{Xn}Ga_{(1-Xn)}N, 0≤Xn<1), where n is a positive integer greater than 1, and when n is odd, 0≤Xn<1, and when n is even, Xn=1, with each of the aluminum nitride layers and each of the aluminum gallium nitride layers having a thickness of 1 to 50 nanometers (nm).

9. The nitride semiconductor device of claim 8, wherein the buffer composite layer has a carbon doping concentration increasing farther from the substrate, gradually increasing from 1E17 to 1E19 cm⁻3 to 1E17 to 1E22 cm⁻3.

10. The nitride semiconductor device of claim 9, wherein the buffer composite layer further includes a second buffer layer sandwiched between the stress control composite layer and the first buffer layer or between the stress control composite layer and the nitride epitaxial composite layer, wherein the second buffer layer is a composite layer comprising alternating stacks of an aluminum nitride layer and an aluminum gallium nitride layer (Al_{Xn}Ga_{(1-Xn)}N, 0≤Xn<1).

11. A manufacturing method for a nitride semiconductor device, comprising:
providing a nitride epitaxial composite layer disposed on a substrate; and
providing a transition composite layer sandwiched between the substrate and the nitride epitaxial composite layer, including a first compound semiconductor and a second compound semiconductor, each selected from a group consisting of binary or ternary compound semiconductors composed of nitrogen (N), aluminum (Al), and gallium (Ga), and combinations thereof,
wherein the transition composite layer has an increasing aluminum content closer to the substrate.

12. The manufacturing method for a nitride semiconductor device of claim 11, wherein the step of providing a transition composite layer comprises a step of providing a stress control composite layer comprising a plurality of aluminum gallium nitride layers (Al_{Xn}Ga_{(1-Xn)}N, 0<Xn<1), where n is a positive integer greater than 1 and represents a layer index, and the smaller the layer index, the closer the aluminum gallium nitride layer is to the substrate with a higher aluminum content.

13. The manufacturing method for a nitride semiconductor device of claim 12, wherein the step of providing a stress control composite layer comprises a step of doping each of the aluminum gallium nitride layers with carbon, with a carbon doping concentration increasing farther from the substrate, gradually increasing from 1E17 to 1E19 cm⁻3 to 1E17 to 1E22 cm⁻3.

14. The manufacturing method for a nitride semiconductor device of claim 13, wherein the carbon doping is performed using one of methane (CH₄), ethylene (C₂H₄), or pentane (C₅H₁₂) as a doping gas, chamber auto-doping, or diffusion.

15. The manufacturing method for a nitride semiconductor device of claim 12, wherein forming the stress control composite layer is performed using metal-organic chemical vapor deposition (MOCVD) or molecular beam epitaxy (MBE) with materials including trimethylgallium (TMGa), triethylgallium (TEGa), trimethylaluminum (TMAl), trimethylindium (TMIn), and ammonia (NH₃).

16. The manufacturing method for a nitride semiconductor device of claim 12, wherein the step of providing a transition composite layer further comprises a step of providing a buffer composite layer having a first buffer layer sandwiched between the stress control composite layer and the nitride epitaxial composite layer or between the stress control composite layer and the substrate, wherein the first buffer layer is a composite layer comprising alternating stacks of an aluminum nitride layer and an aluminum gallium nitride layer (Al_{Xn}Ga_{(1-Xn)}N, 0≤Xn<1), where n is a positive integer greater than 1, and when n is odd, Xn=1, and when n is even, 0≤Xn<1, with each of the aluminum nitride layers and each of the aluminum gallium nitride layers having a thickness of 1 to 50 nanometers (nm).

17. The manufacturing method for a nitride semiconductor device of claim 16, wherein the step of providing a buffer composite layer comprises a step of providing a carbon doping the buffer composite layer, with a carbon doping concentration increasing farther from the substrate, gradually increasing from 1E17 to 1E19 cm⁻3 to 1E17 to 1E22 cm⁻3.

18. The manufacturing method for a nitride semiconductor device of claim 17, wherein the step of providing a buffer composite layer further comprises a step of providing a second buffer layer sandwiched between the stress control composite layer and the first buffer layer or between the stress control composite layer and the nitride epitaxial composite layer, wherein the second buffer layer is a composite layer comprising alternating stacks of an aluminum nitride layer and an aluminum gallium nitride layer (Al_{Xn}Ga_{(1-Xn)}N, 0≤Xn<1).

19. The manufacturing method for a nitride semiconductor device of claim 12, wherein the step of providing a transition composite layer further comprises a step of providing a buffer composite layer having a first buffer layer sandwiched between the stress control composite layer and the nitride epitaxial composite layer or between the stress control composite layer and the substrate, wherein the first buffer layer comprises alternating stacks of an aluminum nitride layer and an aluminum gallium nitride layer (Al_{Xn}Ga_{(1-Xn)}N, 0≤Xn<1), where n is a positive integer greater than 1, and when n is odd, 0≤Xn<1, and when n is even, Xn=1, with each of the aluminum nitride layers and each of the aluminum gallium nitride layers having a thickness of 1 to 50 nanometers (nm).

20. The manufacturing method for a nitride semiconductor device of claim 19, wherein the step of providing a buffer composite layer comprises a step of doping the buffer composite layer with carbon, with a carbon doping concentration increasing farther from the substrate, gradually increasing from 1E17 to 1E19 cm⁻3 to 1E17 to 1E22 cm⁻3.

21. The method of claim 20, wherein the step of providing a buffer composite layer further comprises a step of providing a second buffer layer sandwiched between the stress control composite layer and the first buffer layer or between the stress control composite layer and the nitride epitaxial composite layer, wherein the second buffer layer is a composite layer comprising alternating stacks of an aluminum nitride layer and an aluminum gallium nitride layer (Al_{Xn}Ga_{(1-Xn)}N, 0≤Xn<1).
